(19) United States
(12) Patent Application Publication
(10) Pub. No.: US 2018/0294370 A1
(43) Pub. Date: Oct. 11, 2018

(54) HYBRID SOLAR MODULE

(71) Applicant: INSTITUTE OF NUCLEAR ENERGY RESEARCH, ATOMIC ENERGY COUNCIL, EXECUTIVE YUAN, Taoyuan City (TW)

(72) Inventors: YUEH-MU LEE, Taoyuan County (TW); CHUN-YI CHEN, Taoyuan County (TW); ZUN-HAO SHIH, Taoyuan County (TW); HWEN-FEN HONG, Taoyuan County (TW); CHENG-DAR LEE, Taoyuan County (TW)

(21) Appl. No.: 15/622,563

(22) Filed: Jun. 14, 2017

(30) Foreign Application Priority Data
Apr. 5, 2017 (TW) 106111367

(51) Int. Cl. H01L 31/042; H02S 40/22; H01L 31/049; H02S 30/10

(52) U.S. Cl. CPC H01L 31/042; H02S 40/22; H01L 31/028; H02S 30/10; H01L 31/049

(57) ABSTRACT

The present invention provides a hybrid solar module, including a back plate, a plurality of photovoltaic cells, a plurality of concentrating photovoltaic cells and a light transmissive protective plate. The photovoltaic cells are arranged as an array pattern on the back plate. Each of the concentrating photovoltaic cells is disposed in a gap area, wherein each gap area lies between four adjacent photovoltaic cells, and each group of four photovoltaic cells includes first to fourth photovoltaic cells, with right, lower right and lower sides of the first photovoltaic cell adjacent to the second, third and fourth photovoltaic cells respectively. The transmissive protective plate is disposed on the photovoltaic cells and the concentrating photovoltaic cells.

### CROSS-REFERENCE TO RELATED APPLICATION

This application claims priority from the Taiwan Patent Application No. 106111367 filed on Apr. 5, 2017 at the Taiwan Intellectual Property Office, the content of which is hereby incorporated by reference in its entirety for all purposes.

### BACKGROUND OF THE INVENTION

### 1. Field of the Invention

The present invention is related to a solar module, and more particularly to a hybrid solar module having a plurality of photovoltaic cells and concentrating photovoltaic cells.

### 2. Description of the Related Art

Please refer to FIGS. 1A and 1B, which are a side section view and top plan view respectively. The traditional solar module 1 includes a metal frame 11, a back plate 12, a plurality of photovoltaic cells 13, a transmissive encapsulation film 14 and a transmissive protective plate 15. The metallic frame 11 is used to support and protect the flat panel structure formed of the back plate 12, photovoltaic cells 13, transmissive encapsulation film 14 and transmissive protective plate 15. The photovoltaic cells 13 are disposed on the back plate 12 as an array pattern and encapsulated by the transmissive encapsulation film 14. The transmissive protective plate 15 covers the transmissive encapsulation film 14.

The material of the metallic frame 11 may be light aluminum. The material of the back plate 12 may be polyvinyl fluoride (PVF). The photovoltaic cell 13 may be a crystalline silicon solar cell. The material of the transmissive encapsulation film 14 may be ethylene-vinyl acetate (EVA), which is also known as poly (ethylene vinyl acetate) (PEVA). The material of the transmissive protective plate 15 may be frit. A plurality of the photovoltaic cells 13 may be connected to each other by a plurality of trace lines in a parallel or series configuration. The photovoltaic cells 13 are disposed spaced apart from each other, with areas of the traditional solar module 1 surrounding the photovoltaic cells 13 and in-between adjacent photovoltaic cells 13 that are not part of the photovoltaic cells 13. These areas do not generate electricity and are herein labeled as the useless region (UR). Regarding the power conversion efficiency of crystalline silicon solar cells, it is known that solar cells made of crystalline silicon have a theoretical efficiency limit of less than 30%, and the efficiency is generally only about 18%.

In addition to the photovoltaic cell, another of the current technologies for solar power generation is the concentrating photovoltaic cell, which has a higher power efficiency. For example, when the concentrating photovoltaic cell is a III-V solar cell, its power efficiency may theoretically reach 35% or more and is substantially at about 31%. However, compared with the photovoltaic cell, the manufacturing cost of the concentrating photovoltaic cell is higher, and therefore it is not suitable to pave large areas of ground or buildings with the concentrating photovoltaic cells.

### SUMMARY OF THE INVENTION

In accordance with the issues of the known techniques, the purpose of the present invention is to provide a hybrid solar module.

To realize at least one object of the present invention, disclosed herein is a hybrid solar module, including a back plate, a plurality of photovoltaic cells, a plurality of concentrating photovoltaic cells and a transmissive protective plate. The plurality of photovoltaic cells is arranged as an array pattern on the back plate. Each concentrating photovoltaic cell of the plurality of concentrating photovoltaic cells is disposed in a gap area, wherein each gap area lies between four adjacent photovoltaic cells, and each group of four adjacent photovoltaic cells includes first to fourth photovoltaic cells, with right, lower right and lower sides of the first photovoltaic cell adjacent to the second, third and fourth photovoltaic cells respectively. The transmissive protective plate is disposed on the photovoltaic cells and the concentrating photovoltaic cells.

The hybrid solar module of the present invention, having concentrating photovoltaic cells as described above, may have one or more advantages over the traditional solar module, as follows:

(1) The power generation capability of the hybrid solar module may be greater, even with an occupied area thereof that is the same as that of the traditional solar module, implying that the hybrid solar module may be installed on land or buildings of limited area, and therefore achieving greater power generation for the same area.

(2) Although including the concentrating photovoltaic cells increases the cost, the overall power generation is also enhanced, such that the cost per watt is lower.

(3) The hybrid solar module is similar in structure to that of the traditional solar module, such that the structure of the traditional solar module need not be significantly modified in order to produce the hybrid solar module, and thereby incentivizing manufacturers to produce the hybrid solar module.

(4) Optical microstructures are disposed at positions on the transmissive protective plate corresponding to the concentrating photovoltaic cells in order to focus sunlight onto the concentrating photovoltaic cells and enhance the power generation of the present invention.

(5) The areas of the optical microstructures are small, such that the photovoltaic cell will not be easily damaged even if the focal point shifts.

### BRIEF DESCRIPTION OF THE DRAWINGS

FIGS. 1A and 1B are, respectively, a side section view and top plan is view of the traditional solar module.

FIGS. 2A and 2B are, respectively, a side section view and top plan view of an embodiment of the hybrid solar module of the present invention.

FIG. 2C is a side section view of an embodiment of the concentrating photovoltaic cell of the present invention.

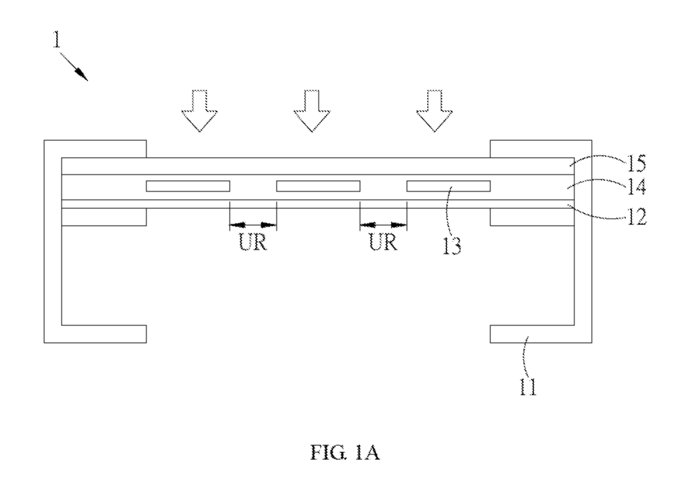

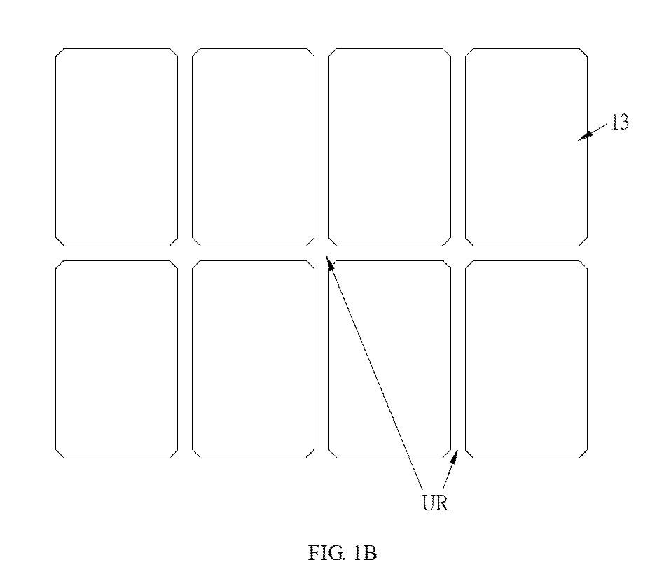

### DESCRIPTION OF THE PREFERRED EMBODIMENTS

For a better understanding of the technical features, details and advantages of the present invention as well as the achievable effects thereof, the present invention is explicitly described below in the form of embodiments with reference to the appended drawings. The drawings present schematics of the present invention and assist with the specification, whereby that which is depicted in the drawings does not necessarily conform to the real dimensions and precise layout of the present invention. That is, the scope of practical implementation of the present invention is not confined by the actual dimensions and layout depicted in the appended drawings.

In addition, it should be noted that, although the terms “first”, “second” and “third” are used to refer to elements in the text below, the described elements are not limited by these terms, which are merely used to distinguish one element from another element. Hence, in the following text, a “first” element may be denoted as a “second” element without departing from teachings of the present invention.

An embodiment of the present invention provides a hybrid solar module, wherein a concentrating photovoltaic cell is disposed in a gap area, wherein each gap area lies between four adjacent photovoltaic cells, so as to improve the power generation efficiency of the hybrid solar module. Due to the small area of the gap area between four adjacent photovoltaic cells, disposing the concentrating photovoltaic solar cell in the gap area described above does not significantly increase the manufacturing cost of the hybrid solar module. Additionally, the cost per watt, which is the manufacturing cost divided by the power generation capacity, of the embodiment of the hybrid solar module of the present invention may be less than that of the traditional solar module.

The embodiment of the hybrid solar module of the present invention may also be used together with a solar tracking system. When the intensity of solar radiation falling on the hybrid solar module is high, then power generation may be enhanced. Also, a certain level of power generation may still be maintained when the intensity of solar radiation is low. In comparison with the traditional solar module, the layout of the embodiment of the hybrid solar module of the present invention remains the same, except, for the addition of the concentrating photovoltaic cells in the gap areas between four adjacent photovoltaic cells. Consequently, an easy modification to the architecture of the traditional solar module is sufficient to produce the hybrid solar module, and so implying that the manufacture of the hybrid solar cell is simple and cost-effective. That is, the architecture of the embodiment of the hybrid solar cell module of the present invention is similar to that of the traditional solar cell module, thereby incentivizing manufacturers to produce the hybrid solar cell module. Furthermore, an active area of the hybrid solar module is approximately the same as that of the traditional solar module, and therefore large amounts of power may be generated with limited use of land area.

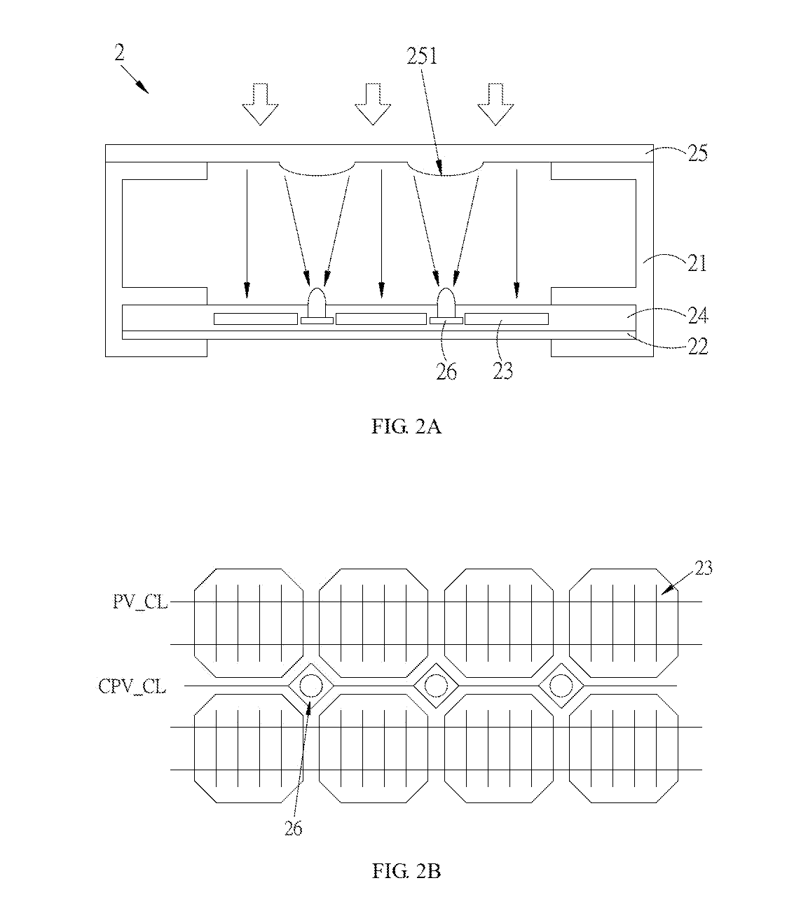

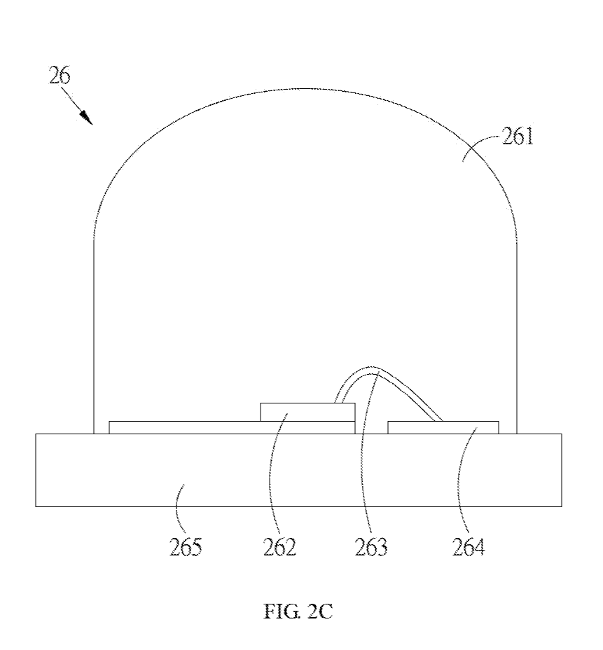

Please refer to FIGS. 2A and 2B, which are, respectively, a side section view and top plan view of an embodiment of the hybrid solar module of the present invention. The hybrid solar module 2 has a flat panel structure formed of a metallic frame 21, a back plate 22, a plurality of photovoltaic cells 23, a transmissive encapsulation film 24, a transmissive protective plate 25 and a plurality of concentrating photovoltaic cells 26. The photovoltaic cells 23 are disposed on the back plate 22 as an array pattern and encapsulated by the transmissive encapsulation film 24. The transmissive protective plate 25 covers the transmissive encapsulation film 24. The concentrating photovoltaic cells 26 are formed in the gap areas between several adjacent photovoltaic cells 23 and are encapsulated by the transmissive encapsulation film 24.

The material of the metallic frame 21 may be light aluminum. The material of the back plate 22 may be polyvinyl fluoride (PVF). The photovoltaic cell 23 may be a crystalline silicon solar cell. The material of the transmissive encapsulation film 24 may be ethylene-vinyl acetate (EVA), which is also known as poly (ethylene-vinyl acetate) (PEVA). The material of the transmissive protective plate 25 may be frit. The concentrating photovoltaic cells 26 may be III-V solar cells. A plurality of the photovoltaic cells 23 may be connected to each other by a plurality of trace lines PV_CL in a parallel or series configuration, and a plurality of the concentrating photovoltaic cells 26 may be connected to each other by a plurality of trace lines CPV_CL in a parallel or series configuration.

Due to the higher cost of the concentrating photovoltaic cells 26 and given that the four corners of each photovoltaic cell 23 each have a missing portion, one concentrating photovoltaic cell 26 may be disposed in the useless region which is a gap area formed by four corners missing a portion, one from each of four adjacent photovoltaic cells 23 in the embodiment of the present invention. Preferably, the length and width of the photovoltaic cell 23 are approximately 10 to 16 cm, while the length and width of the concentrating photovoltaic cell 26 are approximately 0.3 to 10 mm. Furthermore, the four adjacent photovoltaic cells 23 described above include first to fourth photovoltaic cells 23, wherein right, lower right and lower sides of the first photovoltaic cell 23 are adjacent to the second, third and fourth photovoltaic cells 23 respectively.

Additionally, in order to appropriately take advantage of the higher power efficiency of the concentrating photovoltaic cells 26, and therefore enhance the power efficiency of the hybrid solar module 2, the optical microstructures 251 are disposed at positions on the transmissive protective plate 25 corresponding to the concentrating photovoltaic cells 26, wherein the optical microstructures 251 have a positive refractive power and may be convex so as to focus sunlight onto the concentrating photovoltaic cells 26. That is, the transmissive protective plate 25 has a plane portion and convex portions, i.e. it is not fully flat, wherein the convex portions correspond to the concentrating photovoltaic cells 26 so as to focus sunlight onto the concentrating photovoltaic cells 26, and the plane portion corresponds to the photovoltaic cells 23 such that sunlight is directly incident on the photovoltaic cells 23. Hence, the power generated per unit area of the hybrid solar module 2 may be much higher than that of the traditional solar module. Besides, the transmissive protective plate 25 may be manufactured through a method such as glass molding, silicone on glass (SOG), plastic injection molding and so forth, but the manufacturing method is not limited thereto. Furthermore, due to the small area of the optical microstructure 251, the photovoltaic cells 23 will not be easily damaged even if the focal point shifts.

Subsequently, please refer to FIG. 2C, which is a side section view of an embodiment of the concentrating photovoltaic cell of the present invention. An implementation of the concentrating photovoltaic cell 26 described above is depicted in FIG. 2C, but the present invention is not limited thereto. The concentrating photovoltaic cell 26 includes a transparent protective layer 261, a III-V solar cell core 262, a lead 263, a circuit layer 264 and a substrate 265. The circuit layer 264 is positioned on the substrate 265. The III-V solar cell core 262 is positioned on one portion of the circuit layer 264 and connected with the other portion of the circuit layer 264 through the lead 263. The transparent protective layer 261 is used to cover and protect the III-V solar cell core 262, the lead 263, the circuit layer 264 and the substrate 265, wherein the material of the transparent protective layer 261 may be optical silicone and have a dome shape so that the transparent protective layer 261 may be used as a secondary optical element with a light-concentrating effect. The material of the lead 263 may be gold. It should be noted that the choice, as described above, of material and shape of the transparent protective layer 261 and of material of the lead 263 is not meant to confine the scope of the present invention.

On the other hand, please refer to FIGS. 2A and 2B again. In the embodiment of the hybrid solar module 2 of the present invention, the number of the concentrating photovoltaic cells 26 may also be adjusted according to the climate conditions of the location of installation. For example, when installing in a location where solar radiation is abundant, more concentrating photovoltaic cells 26 may be disposed in a plurality of gap areas in the hybrid solar module 2.

Furthermore, the market price of the photovoltaic cell 23 with a length and width of approximately 10 to 16 cm and capable of generating about 130 W of power is about 65 US dollars. The market price of the concentrating photovoltaic cell 26 with a length and width of approximately 0.3 to 10 mm and capable of generating about 23 W of power is about 8.4 US dollars. If a plurality of the photovoltaic cells 23 is arranged as a 4×9 array, there will accordingly be 3×8=24 gap areas with the concentrating photovoltaic cells 26 being disposed thereon. The cost per watt of the traditional solar module in which the photovoltaic cells are arranged in the aforementioned 4×9 array is about 0.5 US dollars, while the cost per watt of the hybrid solar module 2 in which the photovoltaic cells 23 are arranged in the aforementioned 4×9 array together with the concentrating photovoltaic cells 26 therebetween is about 0.483 US dollars. That is, the cost per watt of the hybrid solar module 2 may be reduced by about 3.5% when compared to that of the traditional solar module. Moreover, if the photovoltaic cells 23 are arranged as an M×N array, the ratio of the number of concentrating photovoltaic cells 26 to the number of photovoltaic cells 23 may approach 1 for large M and N, resulting in a cost per watt of the hybrid solar module 2 that may even be reduced to about 0.477 US dollars. That is, the cost per watt of the hybrid solar module 2 may be reduced by up to about 5% when compared to that of the traditional solar module.

In summary, the embodiment of the hybrid solar module of the present invention can help lower the cost per watt when compared to the traditional solar module. The hybrid solar module described above can be produced with a simple modification to the traditional solar module, thus further incentivizing manufacturers to produce the hybrid solar cell. Last but not least, the power generated per unit area of the hybrid solar module described above may be enhanced while the occupied area thereof is the same as that of the traditional solar module.

The descriptions above are merely for the purpose of exemplifying rather than limiting the present invention. Therefore, numerous modifications, variations and enhancements can be made thereto bye those skilled in the art without departing from the spirit and scope of the invention set forth in the claims.

What is claimed is:

1. A hybrid, solar module, comprising:
a back plate;
a plurality of photovoltaic cells, arranged as an array pattern on the back plate;
a plurality of concentrating photovoltaic cells, each disposed in a gap area, wherein
each gap area lies between four adjacent photovoltaic cells,
each group of four adjacent photovoltaic cells comprises first to fourth photovoltaic cells, and p2 right, lower right and lower sides of the first photovoltaic cell are adjacent to the second, third and fourth photovoltaic cells respectively; and
a transmissive protective plate, disposed on the photovoltaic cells and the concentrating photovoltaic cells.

2. The hybrid solar module of claim 1, wherein the transmissive protective plate has convex portions and a plane portion, the convex portions comprise a plurality of optical microstructures, and positions of the optical microstructures correspond to the concentrating photovoltaic cells.

3. The hybrid solar module of claim 1, further comprising:
a transmissive encapsulation film, encapsulating the photovoltaic cells and the concentrating photovoltaic cells.

4. The hybrid solar module of claim 3, further comprising:
a metallic frame, used to support a flat panel structure comprising the back plate, the photovoltaic cells, the concentrating photovoltaic cells, the transmissive encapsulation film and the transmissive protective plate.

5. The hybrid solar module of claim 1, further comprising:
a plurality of first trace lines, electrically connecting the photovoltaic cells to each other; and
a plurality of second trace lines, electrically connecting the concentrating photovoltaic cells to each other.

6. The hybrid solar module of claim 2, wherein the optical microstructures have a positive refractive power to focus sunlight onto the concentrating photovoltaic cells.

7. The hybrid solar module of claim 1, wherein the photovoltaic cell is a crystalline silicon solar cell and the concentrating photovoltaic cell is a III-V solar cell.

8. The hybrid solar module of claim 4, wherein a material of the back plate is polyvinyl fluoride, a material of the transmissive encapsulation film is poly (ethylene-vinyl acetate), a material of the transmissive protective plate is frit and a material of the metallic frame is aluminum.

9. The hybrid solar module of claim 1, wherein both a length and a width of the photovoltaic cell are 10 to 16 cm, and both a length and a width of the concentrating photovoltaic cell are 0.3 to 10 mm.

10. The hybrid solar module of claim 1, wherein the concentrating photovoltaic cell comprises:
a substrate;
a circuit layer, disposed on the substrate;
a lead;
a 111-V solar cell core, disposed on one portion of the circuit layer and connected with the other portion of the circuit layer through the lead; and
a transparent protective layer, covering and protecting the III-V solar cell core, the lead, the circuit layer and the substrate.
